(19) United States
(12) Patent Application Publication
(10) Pub. No.: US 2024/0337318 A1
(43) Pub. Date: Oct. 10, 2024

(54) HIGH TEMPERATURE METAL SEALS FOR VACUUM SEGREGATION

(71) Applicant: Applied Materials, Inc., Santa Clara, CA (US)

(72) Inventors: Muhannad Mustafa, Milpitas, CA (US); Sanjeev Baluja, Campbell, CA (US)

(73) Assignee: Applied Materials, Inc., Santa Clara, CA (US)

(21) Appl. No.: 18/131,212

(22) Filed: Apr. 5, 2023

(51) Int. Cl. F16J 15/10; C23C 16/44; C23C 16/455

(52) U.S. Cl. CPC F16J 15/104; C23C 16/4409; C23C 16/45544

(57) ABSTRACT

Embodiments of the present disclosure are related to directed to a pressure seal for a process chamber. The pressure seal comprises a bottom portion, a compressible middle portion on the bottom portion, and a top portion on the compressible middle portion. The disclosed pressure seal is configured to reduce pumping time of a process region in an interior volume of a processing chamber compared to a process chamber that does not include a pressure seal. Processing chambers including the disclosed pressure seal are configured to process a semiconductor substrate at high temperatures, such as a temperature of greater than or equal to 350° C. Methods of sealing a processing chamber using the disclosed pressure seal are also described.

### TECHNICAL FIELD

Embodiments of the present disclosure generally relate to the field of semiconductor device manufacturing. More particularly, embodiments of the disclosure are directed to a pressure seal to segregate different vacuum spaces in a process chamber.

### BACKGROUND

During semiconductor manufacturing, process chambers often require high temperature vacuum seals, ultra-pure environments and low molecular oxygen content during processing. Process chamber components are connected with an O-ring to prevent metal-metal contact and form a seal. The seal formed is mostly fluid-tight but can allow permeation of some atmospheric gases. The permeation of gases is temperature sensitive, with increased permeation at greater temperatures. Since process chambers are often operated at elevated temperature, gas permeation of the O-ring increases significantly.

In conventional processing chambers, dual seals with sufficient differential pumping are often used with high temperature vacuum assemblies. Application of dual seals has limitations where space constraints are present. Additionally, incorporating dual seals typically has a longer lead time as well and increased cost for custom O-rings.

Therefore, there is a need in the art for improved designs of metal seals, including dual seals, for sealing process chamber environments from ambient gaseous species migration at high temperatures.

### SUMMARY

One or more embodiments of the disclosure are directed to a pressure seal. The pressure seal comprises a bottom portion having a cross-sectional width, a cross-sectional height, a bottom wall and a top wall defining a height of the bottom portion, the bottom wall having a bottom sealing surface, a compressible middle portion on the bottom portion, and a top portion on the compressible middle portion. The compressible middle portion has a dynamic height extending from the top wall of the bottom portion to a top wall of the compressible middle portion. The top portion has walls extending from the top wall of the compressible middle portion. The walls have an arc-shape extending from the top wall of the compressible middle portion to a top end of the top portion and to an inner end of the walls of the top portion.

Additional embodiments of the disclosure are directed to a pressure seal. The pressure seal comprises a ring-shaped bottom portion having a cross-sectional width, a cross-sectional height, a bottom wall and a top wall defining a height of the ring-shaped bottom portion, a compressible middle portion on the bottom portion, and a ring-shaped top portion on the middle portion. The bottom wall of the ring-shaped bottom portion has a bottom sealing surface. The compressible middle portion defines a ring shape and has a dynamic height extending from the top wall of the bottom portion to a top wall of the compressible middle portion. The ring-shaped top portion has walls extending from the top wall of the middle portion. The walls have an arc-shape extending from the top wall of the middle portion to a top end of the top portion and to an inner end of the walls of the top portion.

Further embodiments are directed to a processing chamber. The processing chamber comprises a chamber body having a top wall, a bottom wall and a sidewall containing an interior volume. The chamber body has a slit valve side and a pump port side. The processing chamber further comprises a pumping liner aligned with the slit valve side. The pumping liner has a ring-shaped body, the ring-shaped body having a top surface, a bottom surface, an inner diameter surface, and an outer diameter surface. The processing chamber further comprises a pressure seal as described herein. The pressure seal comprises a bottom portion having a cross-sectional width, a cross-sectional height, a bottom wall and a top wall defining a height of the bottom portion, a compressible middle portion on the bottom portion, and a top portion on the middle portion. The bottom wall of the bottom portion has a bottom sealing surface. The compressible middle portion has a dynamic height extending from the top wall of the bottom portion to a top wall of the middle portion. The top portion has walls extending from the top wall of the middle portion. The walls have an arc-shape extending from the top wall of the middle portion to a top end of the top portion and to an inner end of the walls of the top portion. The processing chamber further comprises an edge ring. The edge ring has an outer diameter surface positioned within the pumping liner so that there is a gap between the outer diameter surface of the edge ring and the inner diameter surface of the pumping liner. The pressure seal is positioned in the gap between the outer diameter surface of the edge ring and the inner diameter surface of the pumping liner to isolate a lower portion of the chamber body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates an isometric view of a pressure seal according to one or more embodiments of the disclosure;

FIG. 2 illustrates a cross-sectional view of the pressure seal of FIG. 1 according to one or more embodiments of the disclosure;

FIG. 3 illustrates a cross-sectional view of the pressure seal of FIG. 1 according to one or more embodiments of the disclosure;

FIG. 4 illustrates a cross-sectional view of the pressure seal of FIG. 1 according to one or more embodiments of the disclosure;

FIG. 5 illustrates a cross-sectional view of the pressure seal of FIG. 1 according to one or more embodiments of the disclosure;

FIG. 6 illustrates a cross-sectional view of the pressure seal of FIG. 1 according to one or more embodiments of the disclosure; and

FIG. 7 illustrates a schematic cross-sectional representation of a processing chamber including the pressure seal according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, the term “in situ” refers to processes that are all performed in the same processing chamber or within different processing chambers that are connected as part of a processing system, such that each of the processes are performed without an intervening vacuum break. As used herein, the term “ex situ” refers to processes that are performed in at least two different processing chambers such that one or more of the processes are performed with an intervening vacuum break. In some embodiments, one or more of the processes is performed without breaking vacuum or without exposure to ambient air.

As used in this specification and the appended claims, the terms “pump liner” and “pumping liner” may be used interchangeably.

One or more embodiments of the disclosure advantageously provide techniques and apparatuses for high temperature vacuum sealing. Some embodiments provide apparatuses for segregating vacuum spaces operating at different pressures. Some embodiments provide apparatuses and methods for efficient removal of gaseous species outgassed from O-rings, minimizing or eliminating negative effects of atmospheric molecular oxygen (O₂) in the processing environment.

Some embodiments of the disclosure are directed to pressure seals with a pump-purge channel. In some embodiments, the channel is continuously purged by an inert gas (e.g., Ar, N₂) to maintain equal pressure in the chamber and the channel. Stated differently, the pressure differential (ΔP) between the channel and the process chamber is minimized. In some embodiments, the pressure different is substantially zero (ΔP=0). The zero pressure differential prevents inert or purge gas (e.g., Ar, N₂) flowing into the reaction space of the chamber.

In some embodiments, a pressure transducer is used to control the pressure in the purge channel relative to the pressure in the process chamber. In some embodiments, the pressure seal has more than one purge gas channel, or the process chamber includes more than one pressure seal with purge gas channels. In some embodiments, each purge channel pressure is individually controlled with respect to surrounding gas pressure. In some embodiments, purge gas (e.g., Ar, N₂) diffusion into the chamber or into a gas channel in the showerhead is substantially zero since the purge channel will be continuously purged and pumped out. In some embodiments, a pulse-purge mechanism is used to remove or eliminate contamination due to O-ring defects or trapped gas.

Embodiments of the disclosure advantageously provide pressure seals that can operate at higher temperatures than conventional elastomer O-rings. Some embodiments of the disclosure use less space to incorporate the pressure seal than conventional dual seals in process chambers. Some embodiments prevent O-ring defect migration and/or chemical byproduct flow into the chamber. In some embodiments, the oxygen (O₂) content in chamber is reduced.

One or more embodiments of the present disclosure provides pressure seals that are particularly useful in deposition processing chambers (e.g., ALD processing chambers and CVD processing chambers) and will be described in that context. One or more embodiments of the present disclosure advantageously provides pressure seals that isolate a process volume from a lower portion of the chamber volume below a substrate support. The pressure seal of various embodiments can be used with many types of process chambers where smaller process spacing is used. Other types of processing chambers and applications for the pressure seals are also within the scope of the invention.

Conventional metal seals, such as dual seals, can segregate gases in static applications. However, in dynamic applications, conventional metal seals have short lifetime due to creep deformation. As used herein, the term “creep” refers to the tendency of a solid material to undergo slow deformation while subject to persistent mechanical stresses. Embodiments of the disclosure advantageously provide pressure seals that have increased lifetime compared to the lifetime of conventional C-seals and the lifetime of conventional dual seals.

As used herein, the term “static” means that the stated component is stationary and does not move. As used herein, the term “dynamic” means that the stated component is capable of moving. One or more embodiments of the disclosure advantageously provide pressure seals that are suitable for either static or dynamic applications.

In operation, in one or more embodiments, the heater pedestal will be actuating up/down during wafer processing in ALD/CVD chambers. At process position, the heater will move towards the showerhead. In some embodiments, the pressure seal will be installed on edge ring skirt (at high temperatures) which can segregate gas flow to a lower part of the chamber volume from process volume at process position. During wafer hand-off, the heater will move down to a slit valve for wafer transfer. Therefore, during wafer hand-off, the pressure seal will undergo cyclic compression during operation. Accordingly, the increased lifetime afforded by the pressure seals described herein advantageously provide improved reliability of gas segregation and volume isolation.

The embodiments of the disclosure are described by way of the Figures, which illustrate pressure seals and processing chambers in accordance with one or more embodiments of the disclosure. The pressure seals and processing chambers shown are merely illustrative possible uses for the disclosed apparatuses, and the skilled artisan will recognize that the disclosed apparatuses are not limited to the illustrated applications.

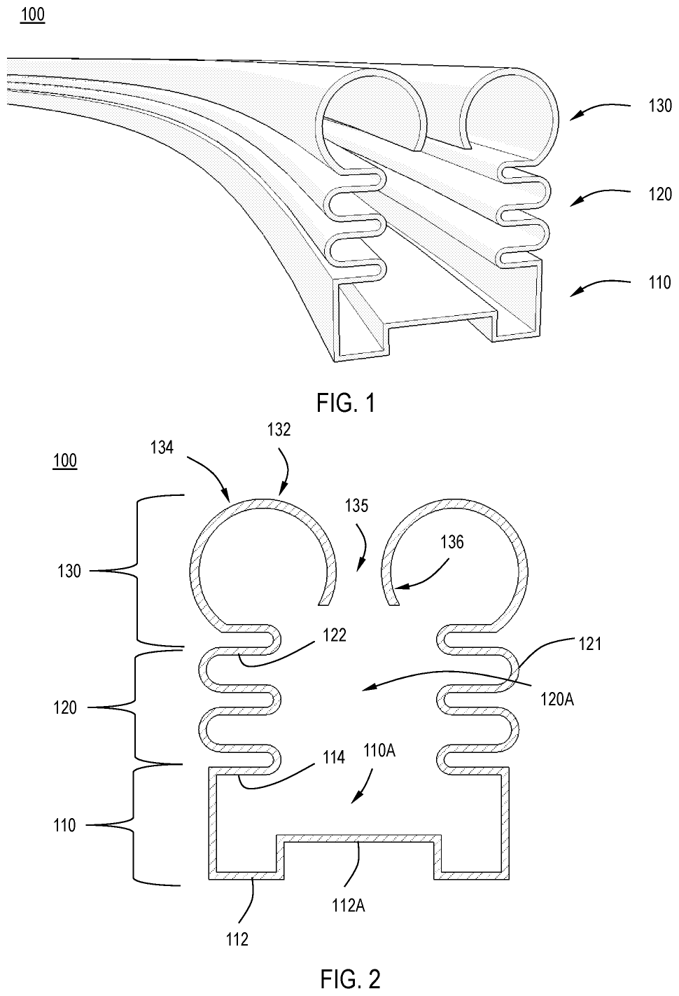

FIG. 1 an isometric view of a pressure seal 100 for a processing chamber in accordance with one or more embodiments of the disclosure. The pressure seal 100 comprises a bottom portion 110, a compressible middle portion 120 on the bottom portion, and a top portion 130 on the compressible middle portion 120. FIGS. 2 through 6 illustrate cross-sectional views of the pressure seal 100 of FIG. 1 according to one or more embodiments of the disclosure.

The bottom portion 110 has a cross-sectional width 110W, a cross-sectional height 110H, and a bottom wall 112 and a top wall 114 defining a height of the bottom portion. In one or more embodiments, the bottom wall 112 has a bottom sealing surface 112A. In one or more embodiments, there are two bottom walls 112 that are disposed on opposite sides of the bottom sealing surface 112A. In some embodiments, the two bottom walls 112 provide a bottom seal, and in turn, provide for improved differential pumping. In some embodiments, the top wall 114 of the bottom portion 110 includes an opening allowing access to an inside 110A of the bottom portion 110. As used herein, the terms “height” and “width” may be used to refer to a specific component, to multiple components, or to an entire/total component as the context will clearly indicate.

In some embodiments, the compressible middle portion 120 has a dynamic height extending from the top wall 114 of the bottom portion 110 to a top wall 122 of the compressible middle portion 120. As used herein, the term “dynamic height” means that the height is capable of moving, i.e., increasing or decreasing. In some embodiments, the compressible middle portion 120 has an open center 120A aligned with the opening in the top wall 114 of the bottom portion 110.

In some embodiments, the compressible middle portion 120 comprises undulating walls 121 extending from the top wall 114 of the bottom portion 110 to the top wall 122 of the compressible middle portion 120. In one or more embodiments, the compressible middle portion 120 defines a bellows shape that oscillates between a first width and a second width greater than the first width. FIG. 6 illustrates oscillation of the first width, which is the dynamic cross-sectional width 120W, to the second width 120W′. In the illustrated embodiment of FIG. 6, the second width 120W′ is greater than the first width 120W. In some embodiments, the oscillating bellows shape changes the width of the compressible middle portion 120, but does not change the width 100W of the pressure seal 100. In some embodiments, the oscillating bellows shape changes the width of the compressible middle portion 120, but does not change the total height 100H of the pressure seal 100.

In some embodiments, the second width 120W′ is closer to the upper end of the range of about 0.25 inches to about 1 inch, such as, for example, in a range of from greater than about 0.5 inches to less than or equal to about 1 inch. In some embodiments, the first width 120W is closer to the lower end of the range of about 0.25 inches to about 1 inch, such as, for example, in a range of from about 0.25 inches to less than or equal to about 0.5 inches.

Referring again to FIGS. 2 through 6, the top portion 130 of the pressure seal 100 has walls 132 extending from the top wall 122 of the compressible middle portion 120. In some embodiments, the walls 132 have an arc-shape extending from the top wall 122 of the compressible middle portion 120 to a top end 134 of the top portion 130 and to an inner end 136 of the walls 132 of the top portion 130. In some embodiments, the walls 132 of the top portion 130 are aligned with the open center 120A of the compressible middle portion 120.

In some embodiments, the top portion 130 has two walls 132 having symmetrical arc-shapes. In some embodiments, the two walls 132 are spaced apart at a center point 135. The skilled artisan will recognize that the center point 135 marked on the Figures is not an actual physical point but a radial center of the two walls 132. In some embodiments, the two walls 132 define dual C-seals. In some embodiments, the two walls 132 provide for improved differential pumping.

In some embodiments, the pressure seal 100 comprises two bottom walls 112 that provide a bottom seal and two walls 132 defining dual C-seals, thereby, providing improved differential pumping. In some embodiments, the pressure seal 100 comprises a low pressure side and a high pressure side. In one or more unillustrated embodiments, the left side is the low pressure side and the right side is the high pressure side. In some unillustrated embodiments, the right side is the low pressure side and the left side is the high pressure side. Embodiments of the disclosure advantageously provide pressure seals 100 for segregating vacuum spaces operating at different pressures, irrespective of which side is the low pressure side and which side is high pressure side.

The pressure seal 100 may have any suitable height. In some embodiments, the pressure seal 100 has a height 100H in a range of from about 0.25 inches to about 1 inch. Stated differently, in embodiments where the pressure seal 100 has a height 100H in a range of from about 0.25 inches to about 1 inch, the height 100H is the total height of the bottom portion 110, the compressible middle portion 120 on the bottom portion 110, and the top portion 130 on the compressible middle portion 120. In embodiments where the pressure seal 100 has a height 100H in a range of from about 0.25 inches to about 1 inch, each of the bottom portion 110, the compressible middle portion 120, and the top portion 130 may have any suitable height such that the total height is in a range of from about 0.25 inches to about 1 inch. In some embodiments, one or more of the bottom portion 110, the compressible middle portion 120, and the top portion 130 have the same height.

The pressure seal 100 may have any suitable width. In some embodiments, the pressure seal 100 has a width 100W in a range of from about 0.25 inches to about 1 inch. In embodiments where the pressure seal 100 has a width 100W in a range of from about 0.25 inches to about 1 inch, each of the bottom portion 110, the compressible middle portion 120, and the top portion 130 may have any suitable width, such that the width 100W is in a range of from about 0.25 inches to about 1 inch. In some embodiments, one or more of the bottom portion 110, the compressible middle portion 120, and the top portion 130 have the same width.

In some embodiments, the pressure seal 100 comprises a height 100H in a range of about 0.25 inches to about 1 inch and a width 100W in a range of from about 0.25 inches to about 1 inch. In some embodiments, the pressure seal 100 comprises a height 100H of about 0.25 inches and a width 100W of about 0.25 inches. In some embodiments, the pressure seal 100 comprises a height 100H of about 0.5 inches and a width 100W of about 0.5 inches. In some embodiments, the pressure seal 100 comprises a height 100H of about 0.75 inches and a width 100W of about 0.75 inches.

In some embodiments, in operation, the compressible middle portion 120 has a spring-like effect. In some embodiments, the compressible middle portion 120 is elastic and returns to its original position after compression of the middle portion 120 and/or after expansion of the middle portion 120.

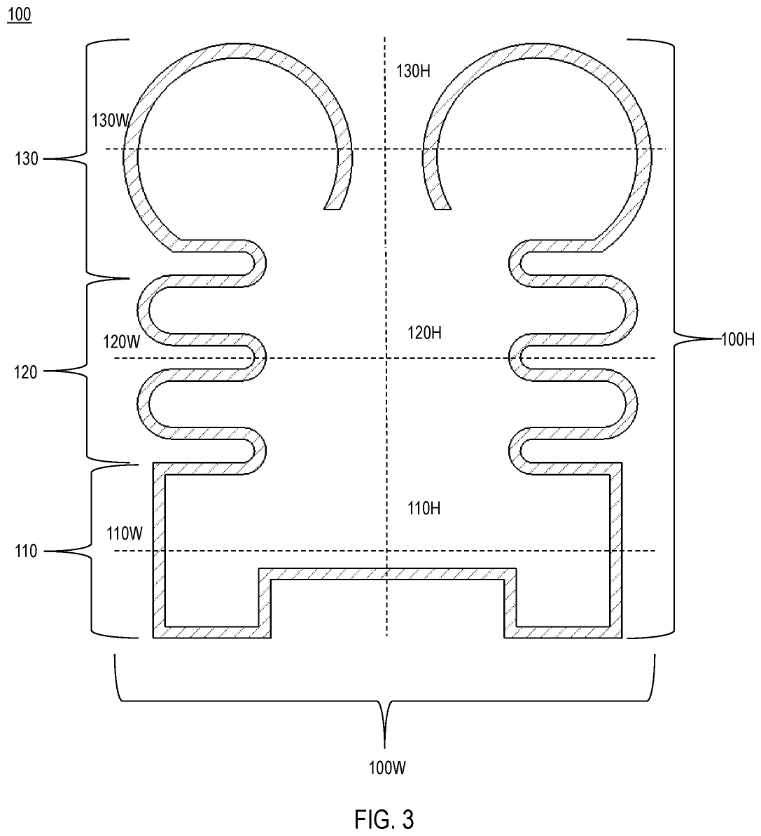

FIG. 3 illustrates the cross-sectional height and cross-sectional width of each component of the pressure seal 100. In FIG. 3, the total height 100H of the pressure seal 100 comprises the total of the cross-sectional height 110H of the bottom portion 110, the dynamic cross-sectional height 120H of the compressible middle portion 120, and the cross-sectional height 130H of the top portion 130. In some embodiments, the pressure seal 100 includes the width 100W, which is in a range of from about 0.25 inches to about 1 inch. In some embodiments, each of the cross-sectional width 110W of the bottom portion 110, the dynamic cross-sectional width 120W of the compressible middle portion 120, and the cross-sectional width 130W of the top portion 130 in a range of from about 0.25 inches to about 1 inch. In one or more embodiments, one or more the cross-sectional width 110W of the bottom portion 110, the dynamic cross-sectional width 120W of the compressible middle portion 120, and the cross-sectional width 130W of the top portion 130 have the same width. In some embodiments, each of the cross-sectional width 110W of the bottom portion 110, the dynamic cross-sectional width 120W of the compressible middle portion 120, and the cross-sectional width 130W of the top portion 130 have the same width.

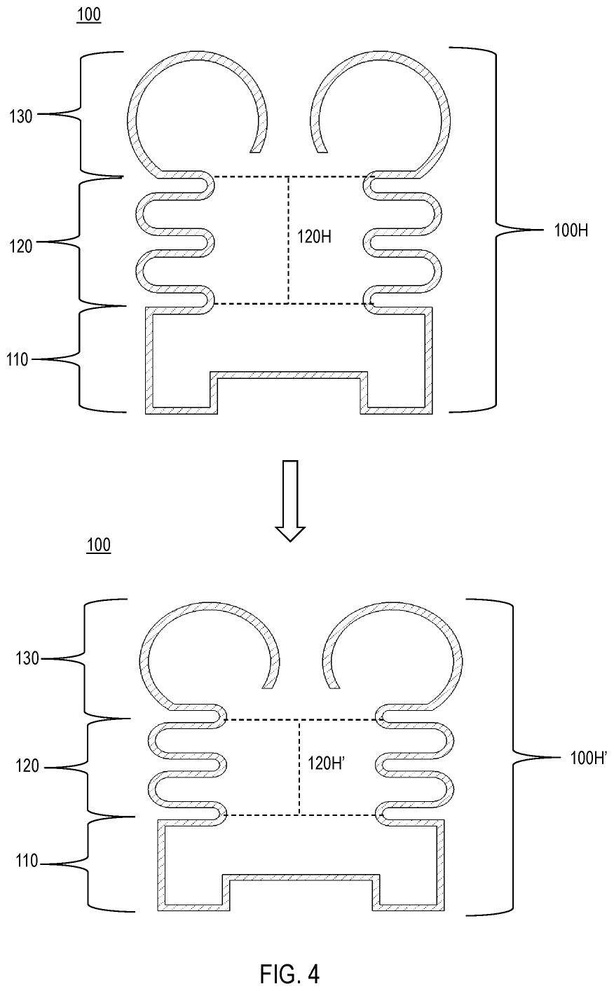

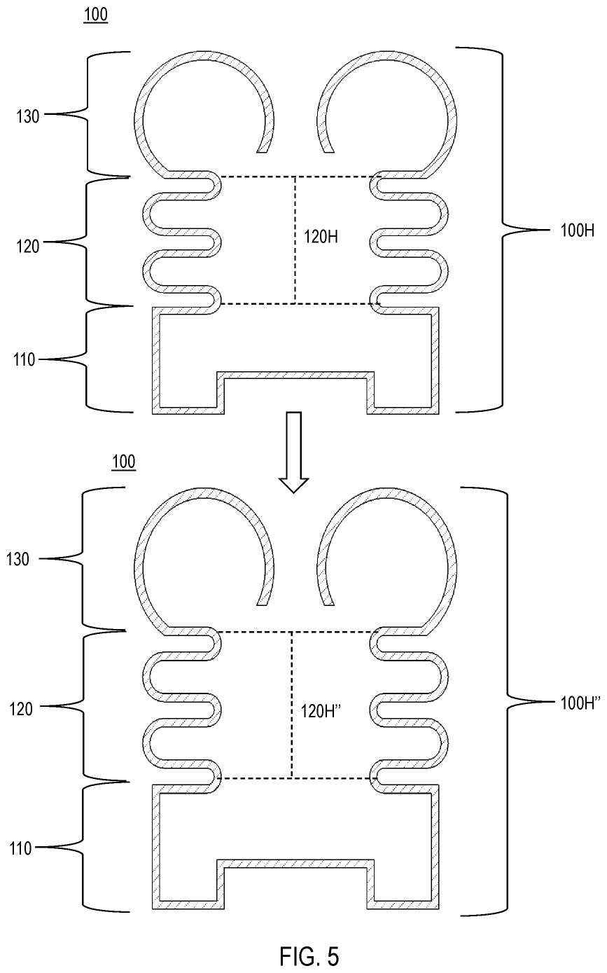

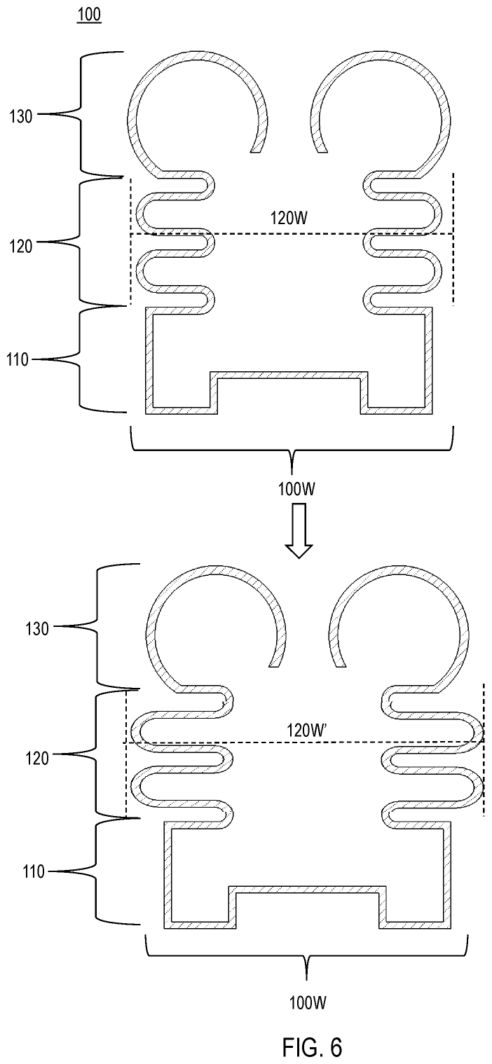

With reference to FIGS. 4 and 5, the compressible middle portion 120 has a dynamic cross-sectional height 120H and a dynamic cross-sectional width 120W that are changeable. In some embodiments, compression of the middle portion 120 moves the top wall 122 of the middle portion 120 toward the bottom portion 110. In some embodiments, compression of the middle portion 120 decreases the dynamic cross-sectional height 120H to form reduced dynamic cross-sectional height 120H′. In one or more embodiments, when the compressible middle portion 120 comprises the reduced dynamic cross-sectional height 120H′, during compression, the total height 100H of the pressure seal 100 is reduced and forms reduced total height 100H′. In some embodiments, the reduced total height 100H′ is within the range of about 0.25 inches to about 1 inch, which is the range of height 100H without compression or expansion. In some embodiments, the reduced total height 100H′ is closer to the lower end of the range of about 0.25 inches to about 1 inch, such as, for example, in a range of from about 0.25 inches to less than or equal to about 0.5 inches. In some embodiments, compression of the pressure seal 100 does not change the width 100W of the pressure seal 100.

In some embodiments, expansion of the middle portion 120 moves the top wall 122 of the middle portion 120 away from the bottom portion 110. In some embodiments, expansion of the middle portion 120 increases the dynamic cross-sectional height 120H to form increased dynamic cross-sectional height 120H″.

In one or more embodiments, when the compressible middle portion 120 comprises the increased dynamic cross-sectional height 120H″, during expansion, the total height 100H of the pressure seal is increased and forms increased total height 100H″. In some embodiments, the increased total height 100H″ is within the range of about 0.25 inches to about 1 inch, which is the range of height 100H without compression or expansion. In some embodiments, the increased total height 100H″ is closer to the upper end of the range of about 0.25 inches to about 1 inch, such as, for example, in a range of from greater than about 0.5 inches to less than or equal to about 1 inch. In some embodiments, expansion of the pressure seal 100 does not change the width 100W of the pressure seal 100.

The pressure seal 100 may comprise any suitable material known to the skilled artisan. In some embodiments, the pressure seal 100 comprises stainless steel having a thickness less than or equal to 5 mils. In some embodiments, the pressure seal 100 comprises stainless steel having a thickness less than or equal to 4 mils, less than or equal to 3 mils, less than or equal to 2 mils, or less than or equal to 1 mil.

The components of the pressure seal 100, including the bottom portion 110, the compressible middle portion 120, and the top portion 130 may define any suitable shape known to the skilled artisan. Stated differently, the components of the pressure seal 100, including the bottom portion 110, the compressible middle portion 120, and the top portion 130 may define any suitable shape such that the pressure seal 100 segregates different vacuum spaces in a deposition process chamber. In some embodiments, one or more of the components of the pressure seal 100 define a polygonal shape. In some embodiments, one or more of the components of the pressure seal 100 are ring-shaped. In one or more embodiments, the pressure seal 100 comprises a ring-shaped bottom portion 110, a compressible middle portion 120, and a ring-shaped top portion 130.

In some embodiments, one or more of the ring-shaped bottom portion 110, the compressible middle portion 120, or the ring-shaped top portion 130 are welded together. In some embodiments, each of the ring-shaped bottom portion 110, the compressible middle portion 120, and the ring-shaped top portion 130 are welded together to form a single component.

Referring again to FIGS. 4 through 6, compression, expansion, and oscillation of the compressible middle portion 120 generally illustrate dynamic applications. Embodiments of the disclosure advantageously provide pressure seals 100 that have increased lifetime and a reduced amount creep deformation compared to conventional C-seals and conventional dual seals.

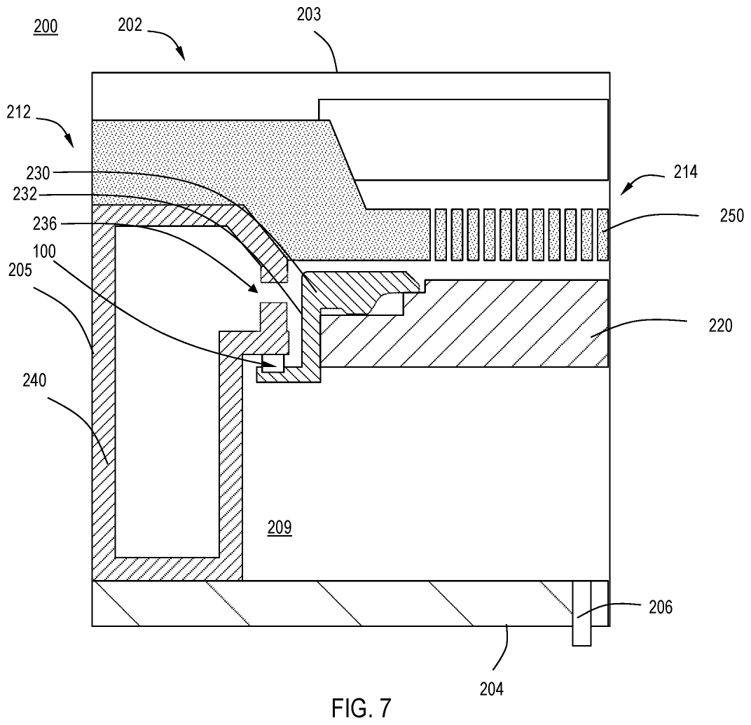

FIG. 7 illustrates a schematic cross-sectional representation of a portion of a processing chamber 200 including the pressure seal 100, according to one or more embodiments of the disclosure. In some embodiments, the processing chamber 200 includes the pressure seal 100 illustrated in FIGS. 1 through 6.

In one or more embodiments, the processing chamber 200 comprises a chamber body 202 having a top wall 203, a bottom wall 204 and a sidewall 205 containing an interior volume 209, and a showerhead 250 (or other gas distribution plate). In some embodiments, the chamber body 202 has a slit valve side 212 and a pump port side 214.

In the illustrated embodiment of FIG. 7, the slit valve side 212 is on the left side and the pump port side 214 is on the right side. The skilled artisan will recognize that the particular arrangement of the slit valve side 212 and the pump port side 214 is merely exemplary and should not be taken as limiting the scope of the disclosure. As used herein, the term “slit valve” refers to an area that may be opened or closed, the area configured to allow for insertion and removal of a substrate.

The processing chamber 200 typically includes a vacuum source (not shown) connected to an exhaust port 206 for maintaining a reduced pressure state within the interior volume 209. In some embodiments, the pump port 214 is positioned adjacent the process region to evacuate gases from the process region. In some embodiments, the pump port 214 is connected to a vacuum source (not shown) for evacuation purposes. The vacuum source connected to the pump port 214 can be the same source or different source than that connected to the exhaust port 206.

In one or more embodiments, the processing chamber 200 comprises a pumping liner 240. In some embodiments, the pumping liner 240 has a ring-shaped body. In some embodiments, the ring-shaped body of the pumping liner 240 has a top surface, a bottom surface, an inner diameter surface, and an outer diameter surface. In some embodiments, the pumping liner is aligned with the slit valve side 212.

In some embodiments, the slit valve side 212 may include an opening (not shown) that has a width sufficient to permit a semiconductor wafer to be transferred therethrough. For example, if the semiconductor wafers being processed have a diameter of 300 mm, the width of the slit valve opening is at least 300 mm between the closest points. In some embodiments, the slit valve opening has a height sufficient to allow a robot end effector supporting a semiconductor wafer to be transferred therethrough.

In embodiments where the pumping liner 240 is aligned with the slit valve side 212, the pumping liner 240 comprises one or more alignment pins (not shown) configured to secure alignment with the slit valve side 212. In some embodiments, the pumping liner 240 has in a range of from 1 alignment pin to 6 alignment pins, including all ranges and sub values therebetween. In some embodiments, the pumping liner 240 has 3 alignment pins.

The processing chamber 200 comprises a pressure seal, such as pressure seal 100 as described herein. The processing chamber 200 comprises an edge ring 230 having an outer diameter surface 232. In some embodiments, the edge ring 230 is positioned within the pumping liner 240 so that there is a gap 236 between the outer diameter surface 232 of the edge ring 230 and the inner diameter surface of the pumping liner 240. The pressure seal 100 is positioned in the gap 236 between the outer diameter surface 232 of the edge ring 230 and the inner diameter surface of the pumping liner 240 to isolate a lower portion, e.g., the interior volume 209 of the chamber body 202.

In one or more embodiments, the pressure seal 100 is mounted onto the edge ring 230. The pressure seal 100 may be mounted to the edge ring 230 by any suitable mounting mechanism or mounting apparatus. In some embodiments, the pressure seal 100 is mounted to the edge ring 230 by a mounting screw (not shown). In one or more embodiments, the mounting screw extends through the bottom sealing surface 112A to connect the pressure seal 100 to the edge ring 230.

In some embodiments, one or more of the ring-shaped bottom portion 110, the compressible middle portion 120, or the ring-shaped top portion 130 are welded together. In some embodiments, each of the ring-shaped bottom portion 110, the compressible middle portion 120, and the ring-shaped top portion 130 are welded together to form a single component. In some embodiments, the ring-shaped bottom portion 110 is mounted to the edge ring 230, and the compressible middle portion 120 and the ring-shaped top portion 130 may be removed. In some embodiment, when each of the ring-shaped bottom portion 110, the compressible middle portion 120, and the ring-shaped top portion 130 are welded together to form the single component, the single component is mounted to the edge ring 230.

Advantageously, the processing chamber 200 is configured to reduce pumping time of a process region in the interior volume 209 compared to a process chamber that does not include a pressure seal. The processing chamber 200 is advantageously configured to process a semiconductor substrate at a temperature of greater than or equal to 350° C.

The pressure seal may be used in one processing chamber, or one or more pressure seals may be used in one or more separate processing chambers. The pump liner may be transferred from one processing chamber to a second, separate processing chamber. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, a suitable processing apparatus may comprise multiple processing chambers (and multiple pump liners) in communication with a transfer station. An apparatus of this sort may be referred to as a multi-chamber processing system.

Additional embodiments of the present disclosure are directed to a method of sealing a processing chamber. In some embodiments, the method comprising: measuring a pressure in a purge gas line downstream of a purge gas line outlet aligned with a purge channel in a gas distribution assembly comprising a gas distribution plate and a lid separated by a pressure seal, such as the pressure seal 100, the purge gas line in fluid communication with a purge channel and a purge gas line inlet, each of the purge gas line inlet and purge gas line outlet aligned with the purge channel; and providing a flow of inert gas into the purge channel so that there is substantially no pressure differential between the gas distribution plate and the purge channel.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A pressure seal comprising:
a bottom portion having a cross-sectional width, a cross-sectional height, a bottom wall and a top wall defining a height of the bottom portion, the bottom wall having a bottom sealing surface;
a compressible middle portion on the bottom portion, the compressible middle portion having a dynamic height extending from the top wall of the bottom portion to a top wall of the compressible middle portion; and
a top portion on the compressible middle portion, the top portion having walls extending from the top wall of the compressible middle portion, the walls having an arc-shape extending from the top wall of the compressible middle portion to a top end of the top portion and to an inner end of the walls of the top portion.

2. The pressure seal of claim 1, wherein the top wall of the bottom portion includes an opening allowing access to an inside of the bottom portion.

3. The pressure seal of claim 2, wherein the compressible middle portion has an open center aligned with the opening in the top wall of the bottom portion.

4. The pressure seal of claim 3, wherein the walls of the top portion are aligned with the open center of the compressible middle portion.

5. The pressure seal of claim 4, wherein the top portion has two walls having symmetrical arc-shapes.

6. The pressure seal of claim 5, wherein the two walls are spaced apart at a center point.

7. The pressure seal of claim 1, having a height in a range of from about 0.25 inches to about 1 inch.

8. The pressure seal of claim 1, having a width in a range of from about 0.25 inches to about 1 inch.

9. The pressure seal of claim 1, wherein the compressible middle portion comprises undulating walls extending from the top wall of the bottom portion to the top wall of the compressible middle portion.

10. The pressure seal of claim 9, wherein the compressible middle portion has a dynamic cross-sectional height and a dynamic cross-sectional width that are changeable upon compression of the middle portion moving the top wall of the middle portion toward the bottom portion or expansion of the middle portion moving the top wall of the middle portion away from the bottom portion.

11. The pressure seal of claim 10, wherein the compressible middle portion is elastic and returns to its original position after compression of the middle portion moving the top wall of the middle portion toward the bottom portion and/or after expansion of the middle portion moving the top wall of the middle portion away from the bottom portion.

12. The pressure seal of claim 1, wherein the compressible middle portion defines a bellows shape that oscillates between a first width and a second width greater than the first width.

13. The pressure seal of claim 1, comprising stainless steel having a thickness less than or equal to 5 mils.

14. A pressure seal comprising:
a ring-shaped bottom portion having a cross-sectional width, a cross-sectional height, a bottom wall and a top wall defining a height of the ring-shaped bottom portion, the bottom wall having a bottom sealing surface;
a compressible middle portion on the bottom portion, the compressible middle portion defining a ring shape and having a dynamic height extending from the top wall of the bottom portion to a top wall of the compressible middle portion; and
a ring-shaped top portion on the middle portion, the ring-shaped top portion having walls extending from the top wall of the middle portion, the walls having an arc-shape extending from the top wall of the middle portion to a top end of the top portion and to an inner end of the walls of the top portion.

15. The pressure seal of claim 14, having a height in a range of from about 0.25 inches to about 1 inch and a width in a range of from about 0.25 inches to about 1 inch.

16. The pressure seal of claim 14, comprising stainless steel having a thickness less than or equal to 5 mils.

17. The pressure seal of claim 14, wherein one or more of the ring-shaped bottom portion, the compressible middle portion, or the ring-shaped top portion are welded together.

18. A processing chamber comprising:
a chamber body having a top wall, a bottom wall and a sidewall containing an interior volume, the chamber body having a slit valve side and a pump port side;
a pumping liner having a ring-shaped body, the ring-shaped body having a top surface, a bottom surface, an inner diameter surface, and an outer diameter surface, the pumping liner aligned with the slit valve side;
a pressure seal comprising:
a bottom portion having a cross-sectional width, a cross-sectional height, a bottom wall and a top wall defining a height of the bottom portion, the bottom wall having a bottom sealing surface;
a compressible middle portion on the bottom portion, the compressible middle portion having a dynamic height extending from the top wall of the bottom portion to a top wall of the middle portion; and
a top portion on the middle portion, the top portion having walls extending from the top wall of the middle portion, the walls having an arc-shape extending from the top wall of the middle portion to a top end of the top portion and to an inner end of the walls of the top portion,
an edge ring having an outer diameter surface positioned within the pumping liner so that there is a gap between the outer diameter surface of the edge ring and the inner diameter surface of the pumping liner, wherein the pressure seal is positioned in the gap between the outer diameter surface of the edge ring and the inner diameter surface of the pumping liner to isolate a lower portion of the chamber body.

19. The processing chamber of claim 18, configured to reduce pumping time of a process region in the interior volume compared to a process chamber that does not include a pressure seal.

20. The processing chamber of claim 18, configured to process a semiconductor substrate at a temperature of greater than or equal to 350° C.
